(19) United States
(12) Patent Application Publication
(10) Pub. No.: US 2008/0271675 A1
(43) Pub. Date: Nov. 6, 2008

(54) Method of forming thin film solar cells

(75) Inventors: Soo Young Choi, Fremont, CA (US); Liwei Li, Sunnyvale, CA (US)

Correspondence Address: SHIRLEY L. CHURCH, ESQ., P.O. BOX 81146, SAN DIEGO, CA, 92138, US

(73) Assignee: Applied Materials, Inc.

(21) Appl. No.: 11/799,528

(22) Filed: May 1, 2007

(51) Int. Cl. H01L 31/18; C23C 16/00

(52) U.S. Cl. 118/715; 427/74

(57) ABSTRACT

A single chamber CVD manufacturing process enables thin film p-i-n solar cells exhibiting collection efficiencies in the range of 9% to 12%, and higher. These collection efficiencies are achieved by: Changing the overall chemical and structural composition of the p-doped layer; Using techniques to remove residual reactants after deposition of the p-doped layer; optionally, applying a buffer layer of a hydrogen-rich amorphous silicon between the p-doped layer and a subsequently deposited intrinsic layer; and, changing the silicon crystalline composition during deposition of an i-doped layer or an n-doped layer. The single chamber process provides a cost of manufacture/solar cell output in $/Watt that is competitive.

### BACKGROUND OF THE INVENTION

1. Field of the Invention

The present invention pertains to a method of forming thin film solar cells. In addition, the present invention pertains to a method of reducing the p-dopant contamination at an interface of a p-doped layer and an intrinsic layer of a thin film solar cell.

2. Brief Description of the Background Art

This section describes background subject matter related to the disclosed embodiments of the present invention. There is no intention, either express or implied, that the background art discussed in this section legally constitutes prior art.

Solar cell technology, a desirable clean energy source, remains too costly when compared with conventional energy sources, thus preventing the widespread use of solar power. Therefore it is desirable to reduce the cost of the manufacture and improve the performance of solar cells. The commonly used methods of solar cell manufacture make use of crystalline silicon, which achieves conversion efficiencies of 15-20%. The energy conversion efficiency, sometimes called CE, is a measure of the amount of absorbed light that is converted to electrical power. Conversion efficiency, CE, is defined as:

$$CE = \frac{{P}_{m}}{E \times {A}_{c}} ,$$

where Pₘ is the power in W at the maximum power point, E is the input light irradiance under standard operating conditions, given in W/m², and A_{c} is the surface area of the solar cell in m². The maximum power point Pₘ is the electrical load at which the cell can deliver the maximum power.

While crystalline silicon solar cells have relatively high conversion efficiencies compared with thin film solar cells, they suffer from high cost. Due to the high cost of crystalline silicon, interest in thin film solar cells keeps growing. Thin film solar cells are frequently deposited on glass, but may be deposited on other materials as well, such as flexible plastics. Thin film solar cells generally consist of a p-doped layer, an intrinsic layer, and an n-doped layer. Typically, thin film solar cells achieve conversion efficiencies (CE) in the range of about 6-10%. The reason for this lower CE (compared with crystalline silicon solar cells) is that the multiple layers of the thin film solar cells are commonly deposited using chemical vapor deposition (CVD) or plasma-enhanced chemical vapor deposition (PECVD) upon a glass or plastic substrate. These deposition techniques generally tend to produce amorphous silicon. Amorphous silicon (a-Si) has lower carrier mobility than single crystal silicon, due to the many dangling bonds which can serve as recombination centers for the electron-hole pairs generated by captured photons.

To overcome the deficiencies of amorphous silicon, microcrystalline silicon (mc-Si) films have been developed. Microcrystalline silicon can exhibit varying grain sizes, from nanometers to microns. Mc-Si has higher carrier mobility and thus leads to improvements in the short circuit current. Mc-Si also shows higher efficiency for the addition of dopants leading to increased electric field within the device. Both of these factors contribute to a higher conversion efficiency by providing an increased collection efficiency of photogenerated carriers. Mc-Si has a bandgap of around 1.1 eV thus being more efficient at absorbing light in the infrared range, while a-Si has a bandgap of around 1.7 eV and absorbs more light in the visible spectrum. Tandem solar cells formed by stacking cells having different bandgaps are well known. This allows each cell in the tandem solar cell to absorb light over a different frequency range, leading to more power generation.

At present, no adequate theory exists to explain which parameters are most significant in obtaining a high efficiency thin film solar cell. It is not possible to generally predict what effect the changing of one process variable will have on the multiple layer structure and thus the resulting CE of the solar cell. For this reason, it is necessary to obtain empirical data for various solar cell designs and for various processing conditions, in an effort to find trends which are beneficial in improving the CE of a solar cell.

It is known that one factor that does contribute to a higher CE is a sharp interface between the p-doped, intrinsic, and n-doped layers. One main problem in obtaining a sharp interface between layers has been the contamination of the intrinsic (i) layer with the p dopant at the interface between a p-doped layer and an intrinsic layer, resulting in a gradual transition in the concentration of the p dopant from the p-layer to the i-layer, rather than a sharp interface. This weakens the electric field in the i-layer, this electric field being necessary to generate a current out of the photo-generated carriers, and results in reduced conversion efficiency.

One common approach to this problem has been to deposit each layer of a thin film solar cell in a separate processing chamber, thus preventing the dopants used for one layer, such as the p-doped layer, from contaminating another layer, such as the intrinsic layer. A problem with this approach has been the limited throughput in terms of substrates per hour, as well as the high cost in terms of equipment because of the large number of chambers required. As a result, this technology still suffers from a high fabrication cost in terms of dollars per watt.

U.S. Pat. No. 5,180,434, DiDio et al., Mar. 11, 1991, “Interfacial Plasma Bars for Photovoltaic Deposition Apparatus”, describes a method of fabricating a p-i-n structure where “gas gates” of a flow of inert gas are used to prevent boron present in a chamber that is used to form the p-doped layer from entering the chamber where the intrinsic layer is subsequently formed.

Lloret et al., in an article entitled “Hydrogenated Amorphous Silicon p-Doping with Diborane, Trimethylboron, and Trimethylgallium”, Applied Physics A 55, pp. 573-581 (1992), describe the formation of a p-i-n structure. They provide a comparison between using diborane, trimethylboron (TMB), or trimethylgallium to form a p-type amorphous silicon layer. Lloret et al. reach the conclusion that TMB is much more thermally stable than diborane, and therefore recommend the use of TMB in a cold wall reactor environment, as a means of reducing contamination of a subsequently deposited i-layer. The authors also mention that the state of the art efficiency (CE) for CVD solar cells is 7%.

EP 631329 A1, Kase et al., Dec. 28 1994, “Amorphous silicon solar cell for integrated solar cells or photo sensors production obtained by forming amorphous silicon layer with p-i-n junction and back electrode layer on insulating transparent substrate with transparent electrode layer”, discloses forming an amorphous silicon-containing solar cell using a reactive gas mixture containing silane, methane, diborane and some trimethylboron, to deposit a p-type amorphous silicon carbide layer. They do not address the boron contamination problem.

U.S. Pat. No. 6,399,873, Sano et al., Feb. 25, 1999, “Stacked Photovoltaic Device”, disclose a stacked device of three solar cells, each constituting a p-doped layer, an intrinsic layer, and an n-doped layer. An amorphous silicon is used as the intrinsic layer in the first cell of the stack, and microcrystalline silicon is used as the intrinsic layer in the second and third cells of the stack. The p-doped layer, the intrinsic layer, and the n-doped layer of each cell are each formed in a separate deposition chamber. Diborane is used as the boron source for p-layer doping.

U.S. Pat. No. 6,700,057, Yasuno, Jun. 25 2002, “Photovoltaic Device”, discloses a photovoltaic device of three stacked solar cells, each having non-single-crystalline silicon layers. The photovoltaic device is an n-i-p structure, where the n-doped, intrinsic, and p-doped layers are all formed in series in a process chamber. Since the n-doped layer, which is a phosphorus-doped amorphous silicon, does not tend to contaminate the process chamber, the chamber is conveniently cleaned after the deposition of the boron-doped p-layer.

The interface between the p-doped layer and an i-doped layer is the major semiconductor junction that is responsible for the electric field that generates the current from the photo-generated carriers. Since photo-generated holes have lower mobility than photo-generated electrons, holes generated close to a p-doped layer can be more effectively collected to contribute to the current of the solar cell. Light usually strikes the thin film silicon solar cells from the p-doped side such that most photo-generated electron-holes are generated near the p/i interface and can be more effectively collected. For this reason, a p-i-n solar cell is preferred to an n-i-p solar cell.

Ballutaud et al., in an article titled “Reduction of the Boron Cross-Contamination for Plasma Deposition of p-i-n devices in a Single-Chamber Large Area Radio-Frequency Reactor”, Thin Solid Films, Vol. 468 (2004), pages 222-225, disclose a method of avoiding the contamination of the interface between a p-doped layer and an intrinsic layer by introducing a gas able to react with the doping agent on the surface of the p-doped layer, after forming the p-layer and prior to the formation of the i-layer. The gases used were said to “fix the doping agent species”, and include ammonia, water, methanol, isopropanol and other alcohols, as well as hydrazine, or other volatile organic amines. The authors conclude that an ammonia flush creates boron-nitrogen molecular complexes which fixes the boron in the p-layer, preventing it from migrating into the intrinsic layer.

Avoidance of the contamination problem with the dopants, by using separate processing chambers for deposition of individual solar cell layers has significantly added to the cost of fabrication of p-i-n solar cells. As previously mentioned, the p-i-n solar cells are preferred because conversion of light into carriers is more efficient when the p layer is uppermost, allowing the interface between the p-doped layer and the intrinsic layer to come in contact with more light.

The solar cell industry is in its infancy, in part due to the cost of producing a system which provides sufficient power generation to justify the cost of a solar cell to a consumer. The cost per power generation, $/Watt, must be reduced by increasing the CE, and by making efficient use of the apparatus used to fabricate the solar cells. A fabrication method is needed which provides higher throughput with less equipment, thereby driving down the fabrication costs, while at the same time maximizing the CE of the solar cell. These needs of the industry have heretofore not been met.

### SUMMARY OF THE INVENTION

It is possible to use a single chamber process to form thin film p-i-n solar cells and still achieve collection efficiencies in the range of 9% to 9.5%, and expectedly higher as development continues. These relatively high collection efficiencies (compared with previous collection efficiencies for thin film solar cells) can be achieved using a single chamber manufacturing process by: 1) altering the overall chemical and structural composition of the p-doped and/or n-doped silicon-containing layer from that previously known art, to provide a silicon-carbide containing composition and structure within the p-doped layer, whereby the collection efficiency (CE) of the solar cell is improved; 2) Using a gas purge and or vacuum pump down to remove residual reactants from the process chamber after formation of a doped silicon-containing layer; and 3) In some instances, applying a buffer layer of a hydrogen-rich amorphous silicon between the a p-doped silicon-containing layer and a subsequently deposited intrinsic silicon-containing layer. The ability to form the thin film solar cells in a single chamber increases efficiency of production so that the cost of manufacture balanced against the output of the solar cell (in $/Watt) has demonstrated that a single chamber production method is acceptable.

A method of depositing all the PECVD layers of a p-i-n solar cell in a single chamber had been developed, while maintaining a relatively high CE for the solar cell, by selection of particular materials and processing conditions to form the thin cell layers. This method is referred to herein as a “single” chamber process. The single chamber process maintains a CE in the range of about 9 or higher, typically between about 9.0 to 9.5, and currently increasing, unexpectedly high CE for a thin film solar cell made in a single chamber.

Prior to development of a “single” chamber process, the most commonly used method of producing a thin film p-i-n solar cell was one in which the p, i, and n layers were each deposited in a separate chamber. This process is referred to herein as a “three” chamber process. In the “three” chamber process, substrate throughput is limited by the need to transfer substrates between processing chambers. Further, in a “three” chamber process, as illustrated in FIGS. 2A and 2B, if a cluster processing system used to fabricate the solar cells includes only one process chamber for deposition of the p-doped layers and/or only one process chamber for deposition of the n-doped layers, the entire cluster processing system is shut down if one of these deposition chambers malfunctions. Even if there were more than one of the p-doped layer and/or n-doped layer chambers, a malfunction of one of these chambers would slow down production substantially. On the basis of the time required for deposition of the various layers, it is common to have fewer p-doped layer and fewer n-doped layer deposition chambers, based on the time required to deposit individual layers.

The “single” chamber process allows for a throughput increase in the range from about 6% to about 35% over the “three” chamber process, depending on the number of chambers in a cluster processing system. The lowest throughput increase of 6% of the “single” chamber process over the “three” chamber process is for a 7 chamber cluster system for a single junction p-i-n process. The highest throughput increase of 35% of the “single” chamber process over the “three” chamber process is for a 5 chamber cluster processing system, which provides a two junction p-i-n process (a tandem cell process), where at least the bottom cell of the two cells is fabricated using micro-crystalline silicon layers.

As discussed above, in a “single” chamber processing method, all of the p, i, and n layers of a p-i-n solar cell are deposited in a single process chamber. The method includes the following steps: a) providing a single PECVD processing chamber configured to deposit a p-doped layer, an intrinsic layer, and an n-doped layer; b) placing a substrate having a surface area of 1 square meter or greater within the PECVD processing chamber; c) forming at least one p-doped layer upon the substrate; d) forming at least one intrinsic layer overlying the p-doped layer; and e) forming at least one n-doped layer overlying the intrinsic layer. When it is desired to produce a tandem solar cell, which includes more than one solar cell in a stacked structure, the process may include the additional steps of f) forming at least one second p-doped layer overlying the n-doped layer of step e); g) forming at least one second intrinsic layer overlying the second p-doped layer of step f); and h) forming a second n-doped layer overlying the second intrinsic layer of step g).

In addition, the single chamber process may include a method of forming a p-i-n solar cell, including a) providing a single PECVD processing chamber configured to deposit a p-doped layer, an intrinsic layer, and an n-doped layer; b) placing a substrate having a surface area greater than 1 square meter or greater within the PECVD processing chamber; c) heating the substrate to a minimum temperature of 150° C. or greater; d) forming a p-doped layer including a silicon-comprising layer doped with boron on the substrate, wherein process chamber wall surfaces adjacent the substrate are held at a temperature of at least 50° C. lower than the substrate temperature; e) forming an intrinsic silicon layer overlying the p-doped layer; and f) forming an n-doped layer including a silicon-comprising layer doped with an n-dopant overlying the intrinsic silicon layer. The process may include the additional steps including: g) forming a second p-doped layer overlying the n-doped layer of step f); h) forming a second intrinsic layer overlying the second p-doped layer of step g); and i) forming a second n-doped layer overlying the second intrinsic layer of step h).

Typically, an apparatus for forming solar cells is configured with multiple chambers, one of which is a load lock docking chamber, which leads to a robot-containing transfer chamber which feeds a number of PECVD processing chambers. The PECVD processing chambers are often arranged in a circular pattern around a transfer chamber. All chambers are in communication with the robot located inside the transfer chamber, which loads and unloads substrates from load lock docking and processing chambers. In the “three” chamber cluster processing system, typically a single processing chamber is dedicated to the deposition of the p-doped layer, while another chamber is dedicated to the deposition of the n-doped layer. Therefore, should the P-chamber or the N-chamber malfunction, the whole cluster processing system goes out of production. By contrast, in a “single” chamber process, each of the processing chambers in the apparatus is configured to deposit a p-doped layer, an intrinsic layer, and an n-doped layer within the same chamber, typically without removing the substrate. The “single” chamber process is more robust, since the inoperability of any one chamber does not shut down production. In addition, the number of substrate transfers is significantly reduced, which provides a processing time savings.

To provide a feasible “single” chamber process, we have developed a method of producing large arrays of thin film solar cells (with areas greater than 1 square meter) using plasma enhanced chemical vapor deposition (PECVD) which employs particular materials and processes. The deposition process is very dependent on the processing chamber volume and substrate surface area. Currently, the scaling up of a process to move to chambers capable of manufacturing larger substrates must be empirically determined. The apparatus used for solar cell fabrication may have a surface area of 10,000 cm² or more, typically 40,000 cm² or more, and commonly 55,000 cm² or more. While the overall processing conditions for each new size needs to be optimized, there are certain variables which have been shown to provide a particular effect on the CE of the thin film solar cell which is fabricated, all other variable held constant.

The radiation transparent substrate which forms the exterior of a solar cell is frequently glass, the electrodes are frequently transparent conductive oxides, such as (for example and not by way of limitation) SnO or ZnO, and the reflective layer is frequently metal, such as (for example and not by way of limitation) Al, Ag, Ti, Cr, Au, Cu, Pt, or alloys thereof. The thin film layers of the solar cell, which are PECVD deposited, are typically silicon-containing layers. The p-doped, intrinsic, and n-doped silicon layers may contain amorphous silicon, microcrystalline silicon, nanocrystalline silicon, or polycrystalline silicon. Microcrystalline silicon is fine-grained polysilicon with grain size on the order of microns. Nanocrystalline silicon is silicon crystallites with grains less than a micron in size embedded in an amorphous matrix. In nanocrystalline silicon, the crystalline volume may be any fraction of the total volume. The p-doped layer is often a silicon carbide alloy with amorphous silicon, which alloy may take various forms depending on the silicon carbide content of the p-doped layer.

Each of the p-doped, intrinsic, and n-doped layers may be a single layer of silicon-containing material, or it may comprise a plurality of layers, where the plurality of layers includes different kinds of silicon. A p-doped, intrinsic, or n-doped layer may contain (for example and not by way of limitation) a first portion which comprises amorphous silicon and a second portion which comprises microcrystalline silicon, by way of example and not by way of limitation. As previously discussed, using a combination of layers having different crystalline structures improves interface qualities and enables capturing of radiation from a broader wavelength range.

The p dopant used in the p-doped layer is frequently a Group III element, such as boron, aluminum, gallium, or indium. Boron is frequently used and the boron source may be (for example and not by way of limitation) diborane, trimethylboron (TMB), triethylboron, boron trifluoride, tris(pentafluorophenyl)boron, pentaborane, or decaborane. A carbon-containing boron source gas is beneficial in the formation of silicon carbide, which is more chemically inert than silicon, thus preventing oxidation of the layer; further, the difference in matrix structure of a p-doped layer containing a silicon carbide alloy provides an improved sharpness of interface with a subsequently applied overlying i-layer of the thin film solar cell. The silicon carbide alloy has a wider bandgap, increases open circuit voltage, and improves light transmission to the interfacially adjacent intrinsic layer where electron-hole pairs are photo-generated. A carbon-containing boron dopant compound (which increases the amount of silicon carbide alloy formed in a p-doped layer) may be selected from the group consisting of trimethylboron (TMB), triethylboron, tris(pentafluorophenyl)boron, carboranes (dicarba-closo-dodecaboranes), and combinations thereof, by way of example and not by way of limitation.

The n dopant is frequently a Group V element, such as phosphorus, arsenic, antimony, or nitrogen. Phosphorus is frequently used, and the phosphorus source may be (for example and not by way of limitation) phosphine. Other phosphorus sources may be tertiarybutylphosphine, trimethylphosphine, or phosphorus trifluoride.

Despite previous assumptions to the contrary, surprisingly, a thin film solar cell deposition process is possible which provides consistent CEs ranging from 9 to 12 for p-i-n solar cells produced in a single chamber. The CE depends on the solar cell design, for example, the tandem two solar cell designs provide a higher CE, and the use of dual layers as i-layers and n-layers, where the dual layers comprise an a-silicon portion and a mc-silicon portion, improve the CE. This CE is expected to increase with further development. Among the important process variables with respect to a single chamber process are the temperature of the substrate, the temperature of the interior surfaces of the deposition chamber, the relative flow rates of the precursor gases as a function of the processing chamber volume (sccm/L), the plasma power density (in W/cm²) and the pressure inside the deposition chamber during the various process steps. The types and combinations of silicon used for the p-doped, intrinsic, and n-doped layers also have a significant effect on performance of the solar cell produced.

In addition, other processing parameters of particular importance include the RF power frequency used for plasma generation, the plasma electrode spacing, the time periods of each of the process steps, the temperature in the processing volume of the process chamber, and the use of purge gases and pump down procedures (during which residual precursors and reaction by-products from a layer deposition are removed prior to deposition of the next layer).

The process for use in a “single” chamber cluster system can be designed to produce solar cells in a manner which minimizes p-dopant contamination of the adjacent intrinsic layer (which may be selected from the group consisting of amorphous silicon, nanocrystalline silicon, microcrystalline silicon, polycrystalline silicon, and combined layers thereof). A reduction in p-dopant contamination results in an increased CE, as a result of the sharper interface between the p-doped layer and the intrinsic layer.

To obtain an excellent thin film solar cell in a “single” chamber process, we have used a carbon-containing boron compound to produce the p-doped layer. Use of such a carbon-containing boron compound provides both the benefits of a silicon carbide alloy (discussed above) in the p-layer and a sharper interface between the p-layer and an interfacially adjacent i-layer. In one embodiment which provided excellent results, the carbon-containing boron compound which was used was trimethyl boron, TMB. In the “single” chamber process, when using TMB as the boron source (for example, and not by way of limitation), the chamber walls were not heated and thus were kept colder than the heated substrate, typically about 50° C. or more below the substrate temperature, and the pressure was maintained in the range from about 1 torr to about 100 torr. The p-doped amorphous silicon layer had a thickness ranging from about 60 Å to about 300 Å, and was formed with typical plasma gas flow rates of trimethylboron in the range from about 0.005 sccm/L to about 0.05 sccm/L, in combination with a methane gas flow rate in the range from about 1 sccm/L to about 15 sccm/L, to assist in the formation of a silicon carbide alloy.

Optionally, the processing chamber was purged with a purge gas (typically Argon) for at least about 60 seconds after the formation of the p-doped layer, followed by a pump down to about 8×10⁻⁶ torr before the formation of an intrinsic layer. In an alternative option to the purge gas step, the processing chamber was pumped down to about 2×10⁻⁵ torr or below, in some embodiments typically to about 8×10⁻⁶ torr or below, directly after the formation of the p-doped layer and before the formation of the intrinsic layer. Either as an alternative to the above optional steps, or in addition, prior to one of these steps, a buffer layer of hydrogen-rich amorphous silicon may be formed on top of the p-doped layer prior to the formation of the intrinsic layer. The optional buffer layer may have a thickness from about 30 Å to about 300 Å, and is formed with typical flow rates of SiH₄ ranging from 0.3 sccm/L to 5 sccm/L, and H₂ ranging from 3 sccm/L to 100 sccm/L.

### BRIEF DESCRIPTION OF THE DRAWINGS

FIG. 1 shows a PECVD processing chamber of the kind which can be used to practice the method of the present invention

FIG. 2A shows a comparative PECVD cluster processing system 200 which may be used to carry out a “three” chamber process. The cluster processing system includes a load lock docking chamber 202, and five film deposition chambers (one P chamber 206, three I chambers 210, one N chamber 212) of the kind shown in FIG. 1, arranged around a transfer chamber 204 which contains a robot 208.

FIG. 2B shows a comparative PECVD cluster processing system 201 for a “three” chamber process apparatus which includes a load lock docking chamber 202, and seven film deposition chambers (one P chamber 206, five I chambers 210, one N chamber 212) of the kind shown in FIG. 1, arranged around a transfer chamber 204 inside which is a robot 208. The PECVD cluster processing system 201 is essentially the same as the cluster processing system 200 except that there are five I chambers 210 rather than the three I chambers 210 shown in cluster processing system 200.

FIG. 2C shows two PECVD cluster processing systems which are useful in practicing embodiments of the present invention. The two cluster processing systems may be used alone or in combination. Cluster processing system 203 includes a load lock docking chamber 222 and five film/layer-depositing chambers, 230, each of which is capable of depositing a p-doped layer, an i-layer, and an n-doped layer, where each layer comprises a-silicon. Cluster processing system 205 includes a load lock docking chamber 223 and five film/layer-depositing chambers 232, each of which is capable of depositing a p-doped layer, an i-layer, and an n-doped layer, where each layer comprises microcrystalline silicon (mc-silicon). (However, the film/layer depositing chambers which may deposit microcrystalline silicon may also be capable of depositing a-silicon.) Each of these cluster processing systems is referred to as a “single” chamber process apparatus.

FIG. 2D shows a single PECVD cluster system 240, which includes a load lock docking chamber 242 and seven film/layer-depositing chambers, each of which is capable of depositing a p-doped layer, an i-layer, and an n-doped layer. The processing chambers 250 are capable of depositing a-silicon-containing layers, while the processing chambers 252 are capable of depositing mc-silicon-containing layers (or amorphous silicon, a-silicon). This cluster processing system is also referred to as a “single” chamber process apparatus, because a p-doped layer, an i-doped layer, and a n-doped layer may be deposited in any of the processing chambers 250, 252, and combinations thereof.

FIG. 3 shows a single stack thin film solar cell of the kind described in Example 1 herein.

FIG. 4 shows a tandem thin film solar cell of the kind described in Example 2 herein.

FIG. 5 shows a tandem thin film solar cell of the kind described in Example 3 herein.

### DETAILED DESCRIPTION OF EXEMPLARY EMBODIMENTS

As a preface to the detailed description presented below, it should be noted that, as used in this specification and the appended claims, the singular forms “a”, “an”, and “the” include plural referents, unless the context clearly dictates otherwise.

When the word “about” is used herein, this is intended to mean that the nominal value presented is precise within ±10%.

### I. APPARATUS FOR PRACTICING THE INVENTION

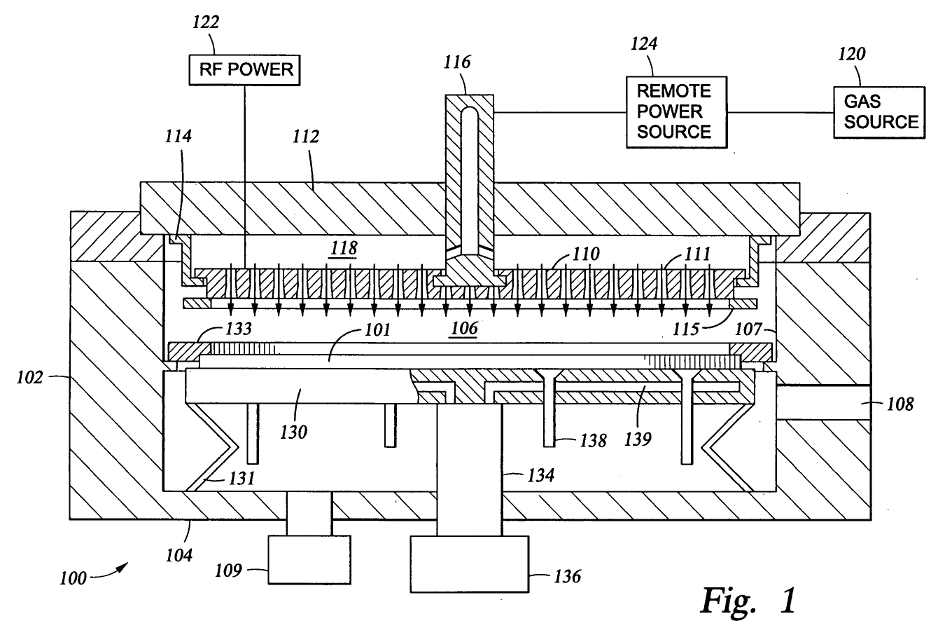

The example plasma enhanced chemical vapor deposition (PECVD) processes described herein were carried out in a parallel plate processing chamber, such as the one available from AKT™, a division of Applied Materials, Inc., Santa Clara, Calif. FIG. 1 is a schematic cross-section of one embodiment of a PECVD chamber 100 in which the method or part of the method of the present invention may be carried out. It is contemplated that other deposition chambers may be utilized to practice the present invention.

The example processing chamber 100 generally includes walls 102, a bottom 104, a showerhead 110, and substrate support 130 which define a process volume 106. The process volume 106 is accessed through a “slit” valve 108 such that a substrate, such as substrate 101, may be transferred into and out of the chamber 100. The substrate support 130, which acts as a susceptor/electrode, supports the substrate 101. The substrate support 130 is coupled to a lift column 134, which is coupled to a lift system 136 so that substrate support 130 can be raised and lowered within the interior of process chamber 100. The lift column 134 additionally provides a conduit for electrical and thermocouple leads (not shown) between the support assembly 130 and other components (not shown) of the system 100. A shadow form 133 may optionally be used in conjunction with the substrate 100. Lift pins 138 are moveably disposed through the substrate support 130 to lift a substrate 101 above the substrate support 130, so that substrate 101 can be easily removed from process chamber 100 by a robot (not shown). The substrate support assembly 130 may also include heating and/or cooling elements 139 to the maintain substrate support assembly 130 at a desired temperature. The substrate support 130 may also include grounding straps 131 to provide RF grounding at the periphery of the support. Examples of grounding straps are disclosed in U.S. Pat. No. 6,024,044 issued on Feb. 15, 2000 to Law et al. and U.S. patent application Ser. No. 11/613,934 filed on Dec. 20, 2006 to Park et al., which are both incorporated by reference in their entirety to the extent not inconsistent with the present disclosure.

The showerhead 110, sometimes called a diffuser plate or a gas distribution plate, is coupled to a backing plate 112 at its periphery by a suspension 114, sometimes called a hanger plate. The showerhead 110 and the suspension 114 may alternatively comprise a single unitary member. The suspension 114 maintains the showerhead 110 and the backing plate in a spaced-apart relation, thereby defining a plenum 118. The showerhead 110 may also be coupled to the backing plate by one or more center supports 116 to help prevent sag and/or control the curvature of the showerhead 110. The plenum 118 provides for a uniform distribution of the gases across the width of the showerhead. The showerhead 110 is provided with a plurality of gas passages 111 to allow a predetermined distribution of film-forming precursor gases (not shown) to pass through the showerhead. In one embodiment, the showerhead 110 provides for a uniform distribution of gas flow from the plenum 118 to the substrate 101. A gas distribution shield 115 may be provided around the edges of the showerhead, to reduce gas flow around the periphery of showerhead 110, to prevent edge build up of film on the substrate 101.

A gas source 120 is in communication with the backing plate 112 to provide gas through the backing plate 112 and through the showerhead 110 to the upper surface (not shown) of substrate 101. A vacuum pump 109 is in communication with chamber 100 to control process volume 106 at a desired pressure. An RF power source 122 is coupled to the backing plate 112 and/or to the showerhead 110 to provide a RF power to the showerhead in a manner such that the showerhead 110 acts as a first electrode, while the substrate support 130, which is grounded, acts as a second electrode, so that an electric field is created between the showerhead 110 and the substrate support 130. This combination of electrodes permits the generation of a plasma (not shown) in the process volume 106, where the plasma is created from the gases which flow from the showerhead 110. Various RF power frequencies may be used, such as a frequency between about 0.3 MHZ and about 200 MHZ. In one commonly used embodiment, an RF power frequency of 13.56 MHZ is used. Examples of showerheads are disclosed in U.S. Pat. No. 6,477,980 issued on Nov. 17, 2006 to Choi et al., and U.S. Publication 2006/0060138 published on Mar. 23, 2006 to Keller et al, which are all incorporated by reference in their entirety to the extent not inconsistent with the present disclosure.

A remote plasma source 124, such as an inductively coupled remote plasma source, may also be in communication with the plenum 118, so that remotely-generated plasma may be used as a cleaning plasma to clean process chamber components between film/layer deposition steps which are carried out in process volume 106. The cleaning plasma may be further excited by the RF power source 122 provided to the showerhead. Suitable plasma source gases used to generate the cleaning plasma may include, by way of example and not of limitation, NF₃, F₂, and SF₆. Examples of remote plasma sources are disclosed in U.S. Pat. No. 5,788,778, issued Aug. 4, 1998 to Shang et al., which is incorporated by reference to the extent not inconsistent with the present disclosure. In one embodiment, chamber 100 may accommodate a substrate 101 with a surface area of 10,000 cm² or more, typically 40,000 cm² or more, and commonly 55,000 cm² or more.

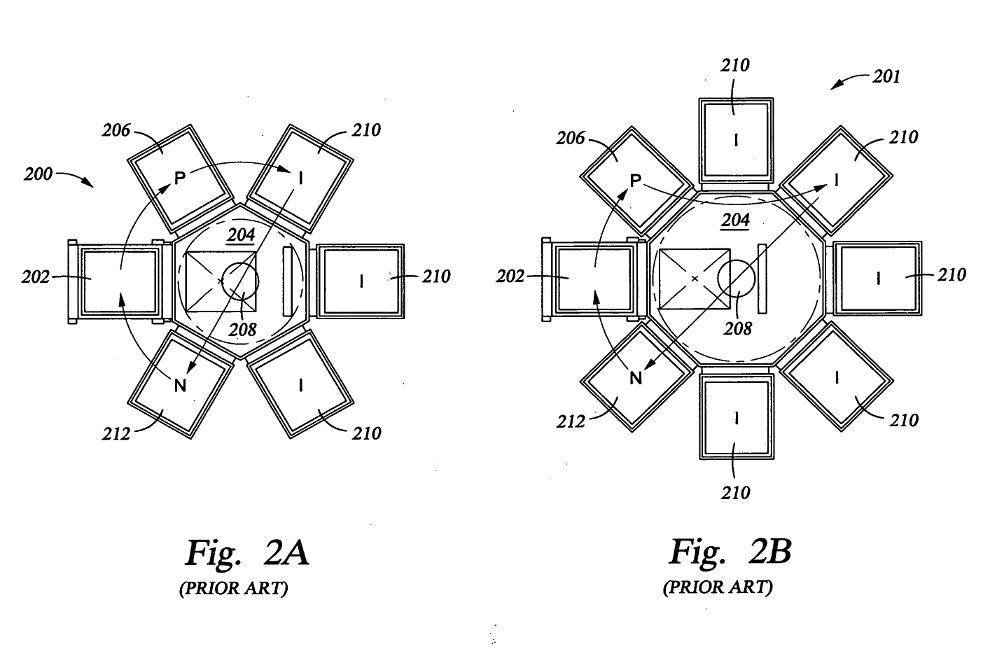

FIG. 2A shows a comparative example of a PECVD cluster system chamber arrangement 200, which is configured for the “three” chamber process. In the “three” chamber process, a total of three different processing chambers are required to form a single stack p-i-n solar cell. The comparative cluster processing system includes a chamber 206 configured to deposit a p-doped layer, a chamber 210 configured to deposit an intrinsic layer, and a chamber 212 configured to deposit an n-doped layer. In FIG. 2A, a load lock docking chamber 202 is in communication with a transfer chamber 204 which contains at least one robot 208 which is used to move substrates from the load lock docking chamber 202 into and out of the transfer chamber 204, and from the transfer chamber 204 into and out of the various processing chambers 206, 210, and 212. It is understood that a different number of processing chambers may be used.

The load lock docking chamber 202 allows substrates to be transferred between an ambient environment outside the system and a transfer chamber 204 which is kept under a vacuum environment. The load lock chamber 202 includes one or more evacuatable regions (not shown) holding one or more substrates. The evacuatable regions are pumped down during input of the substrates into the cluster system 200. The automated robot 208 loads and unloads the substrates into the appropriate chamber, and unloads the finished stack back to the load lock docking chamber 202. In the “three” chamber process, the robot transfers a substrate from the load lock docking chamber 202 into the P chamber 206. Once the p-doped layer is formed, the robot unloads the substrate from the P chamber into one of the available I chambers 210, and loads another substrate into the P chamber 206. When deposition of the intrinsic layer in one of the I chambers is complete, the robot 208 transfers the substrate from that I chamber into the P chamber 212, for the formation of the n-doped layer. Once the n-doped layer is complete, the robot transfers the substrate back to the load lock docking 202, where the substrate is removed.

There are three I chambers used in combination with one P chamber and one N chamber, because the i-layer deposited in the I chamber is typically much thicker than the p-doped or n-doped layer and requires a longer deposition time period. To optimize performance of a cluster system 200, the number of P chambers, I chambers, and N chambers can be optimized based on the product which is to be produced in cluster system 100. As with respect to Examples 1-3, below, deposition of the intrinsic layer can take as much as 20-50 times longer (depending on the specific embodiment) than the deposition of the p-doped layer. The five (or other number of) chambers are individually configured with their own power source 122, gas source 120, and remote plasma cleaning source 124 (shown in FIG. 1, but not shown in FIG. 2A).

FIG. 2B shows another comparative cluster processing system which may be used to carry out the “three” chamber process, configured for seven processing chambers. Other than having five I chambers 210 (rather than 3 as shown in FIG. 2A), this system is identical to that of FIG. 2A. The five I chambers 210 allow for an increased throughput of substrates.

Traditionally, the “three” chamber process has been utilized to avoid any contamination of intrinsic layers in the solar structure by the dopants from an interfacially adjacent p-doped or n-doped layer. One of the main causes of this contamination is the formation of dopant residues on the interior surfaces of the processing chamber. The dopant residues are sputtered off these interior surfaces during subsequent plasma processing in which additional layers are deposited, through a process known as plasma recycling. The sputtered-off residues contaminates the subsequently deposited layers.

Prior to the present “single” chamber process, a reliable and consistent method of obtaining high quality p-i-n stacks, where all the silicon-containing layers are formed in a single chamber, had not been available. The subject matter of the present invention relates to a method of reducing the contamination of the interface between the p-doped layer and the intrinsic layer, and to a method of creating p-doped layers which are chemically and structurally different from p-doped layers of the past, so that an improved performance of the p-doped layer can be obtained. By reducing the contamination at the interface between the p-doped layer and a subsequently deposited silicon-containing layer, and improving the performance of the p-doped layer in general, it is possible to obtain a satisfactory performance from a solar cell produced in a “single” chamber process.

As previously discussed herein, and as discussed in more detail subsequently, there are solar cell configurations which make use of a combination of silicon-containing layers which are based on a-silicon used in combination with silicon-containing layers which are based on microcrystalline silicon (mc-silicon). However, the process chamber configuration which is required for the deposition of an a-silicon-containing layer is substantially different from the process chamber configuration which is required for the deposition of a mc-silicon-containing layer. FIG. 2C shows an embodiment of the “single” chamber process of the present invention, where two cluster processing systems 203 and 205 are used in combination to permit the formation of a-silicon-containing layers in the process chambers of cluster system 203, and the formation of mc-silicon-containing layers in the process chambers of cluster processing system 205. A robot-based transfer mechanism 226 is used to transfer substrates between cluster systems 203 and 205, so that solar cells which make use of a combination of a-silicon-containing layers and mc-silicon-containing layers can be fabricated. The robot-based transfer mechanism may be pressure isolated in one envelope with cluster processing systems 203 and 205, or may be separately pressured.

A processing chamber 230 in cluster processing system 203 is configured to deposit a p-doped layer, an i-doped layer, and/or an n-doped layer which contains a-silicon. A processing chamber 232 in cluster system 205 is configured to deposit a p-doped layer, an i-doped layer, and/or an n-doped layer which contains mc-silicon (or a-silicon). The robot 228 transfer substrates from the load lock docking chamber 222 of cluster system 203 into and out of cluster system 203. The robot 228 transfers substrates from the load lock docking chamber 223 of cluster system 205 into and out of cluster system 205. In instances where a tandem solar cell is fabricated wherein one portion of the solar cell is fabricated using only an a-silicon-containing material and another portion of the solar cell is fabricated using only a mc-silicon-containing material, the processing system shown in FIG. 2C may be advisable. This is because the cost of the apparatus used to fabricate the solar cells is reduced.

However, in instances where a tandem solar cell is fabricated, in which it is desired to have a layer of an a-silicon containing material interfacially adjacent to a layer of a mc-silicon containing material, the processing system shown in FIG. 2C is not advantageous in terms of making the best use of the entire combination of processing chambers, because it may require a vacuum break between the formation of the layer of a-silicon-containing material and the layer of mc-silicon-containing layer in some instances. Further, the number of robot handling operations is increased.

FIG. 2D shows a processing cluster system 240 which is configured to deposit a p-doped layer, an i-doped layer, and/or an n-doped layer in each processing chamber. However processing chambers 250 are configured to deposit layers which contain a-silicon, while processing chambers 252 are configured to deposit layers which contain mc-silicon. This kind of cluster system is more expensive to manufacture, due to the complexities of being able to deposit both kinds of layers in a single system. However, it is possible to form p-doped layers, i-layers, and n-doped layers which make use of different silicon-containing compositions and structures in a single system, without breaking vacuum. For example a substrate (not shown) can be transferred from load lock docking chamber 242 into transfer chamber 244 using robot 248. The substrate is then transferred into a processing chamber 250 in which an a-silicon-containing layer is deposited. Subsequently, robot 248 transfers the substrate back into transfer chamber 244, from which the substrate is transferred into a processing chamber 252 in which a mc-silicon-containing layer is deposited. In instances where a tandem solar cell is fabricated where one portion of a solar cell is fabricated using an a-silicon-containing material and another portion of the solar cell is fabricated using a mc-silicon-containing material, the processing system shown in FIG. 2D may be advisable.

One skilled in the art, upon comparison of the “three” chamber processing scheme shown in FIGS. 2A and 2B with the “single” chamber processing scheme shown in FIGS. 2C and 2D will recognize the advantages to using a “single” chamber processing scheme, in terms of throughput rate of solar cell fabrication. In the case of a “three” chamber processing system, should the P-chamber or the N-chamber malfunction, the entire cluster system must be shut down until the P-chamber or the N-chamber is repaired. In a “single” chamber processing system, when one processing chamber goes down, the other chambers remain operational to produce solar cells. Further, the required number of substrate transfers between chambers reduces time efficiency. In a “single” chamber cluster processing system, when one processing chamber malfunctions, the system continues to operate in the regularly operating chambers, with the need for substrate transfer operations being minimal. As previously discussed, in certain embodiments of the “single” chamber invention, one cluster system may be used to deposit the top cell of a tandem stack solar cell, while a different cluster system is used to deposit the bottom cell. In other embodiments, both the top and bottom cell may be deposited within the same cluster system.

Tables 1-3 below show the throughput gains of the “single” chamber process compared with a “three” chamber process in terms of substrates per hour. Table 1 shows the “three” chamber process throughput for both 5 and 7 chamber configurations, for a single stack, top cell of a dual stack, and bottom cell of a dual stack solar cell. Table 2 shows the throughput for the “single” chamber process of the present invention, for both a 5 chamber and a 7 chamber configuration, for a single stack, top cell of a dual stack, and bottom cell of a dual stack. Table 3 compares the throughput of the “single” chamber process with the “three” chamber process.

As can be seen in Table 3, the “single” chamber process provides for a throughput increase in the range from about 6% to about 35% over the “three” chamber process. The lowest throughput increase of 6% of the “single” chamber process over the “three” chamber process is for the 7 chamber arrangement for a single junction p-i-n process. The highest throughput increase of 35% of the “single” chamber process over the “three” chamber process is for the 5 chamber arrangement for a bottom cell of a tandem cell process.

TABLE 1
Three Chamber Processing System

| | | | | | | | | Final |
|---|---|---|---|---|---|---|---|---|
| | Chamber Configuration | | | | | | | Throughput |
| Three Chamber | Total number | | | | Throughput | | | Substrates/ |
| Process | of chambers | P | I | N | P | I | N | hour |
| Single junction | 5 | 1 | 3 | 1 | 24.6 | 11.9 | 21.6 | 11.9 |
| PIN | 7 | 1 | 5 | 1 | 24.6 | 20 | 21.6 | 20 |
| Top Cell PIN | 5 | 1 | 3 | 1 | 24.6 | 12.7 | 16.5 | 12.7 |
| a-Si/mc-Si tandem | 7 | 1 | 5 | 1 | 24.6 | 21.2 | 16.5 | 16.5 |
| Bottom Cell PIN | 5 | 1 | 3 | 1 | 10.9 | 5.4 | 20.5 | 5.4 |
| a-Si/mc-Si tandem | 7 | 1 | 5 | 1 | 10.9 | 8.9 | 20.5 | 8.9 |

TABLE 2
Single Chamber Process

| Single Chamber | Chamber | | | |
|---|---|---|---|---|
| Process | Configuration | | | Final |
| 60 sec pump-down | Total number | | Throughput | Throughput |
| after P layer dep. | of chambers | P/I/N | P/I/N | substrates/h |
| Single junction | 5 | 5 | 15.2 | 15.2 |
| PIN | 7 | 7 | 21.3 | 21.3 |
| Top Cell PIN | 5 | 5 | 14.7 | 14.7 |
| a-Si/mc-Si tandem | 7 | 7 | 20.5 | 20.5 |
| Bottom Cell PIN | 5 | 5 | 7.3 | 7.3 |
| a-Si/mc-Si tandem | 7 | 7 | 10.3 | 10.3 |

TABLE 3
Single Chamber vs. Three Chamber

| Single Chamber | Total | One | Two | Throughput |
|---|---|---|---|---|
| vs. | number of | Chamber | Chamber | Increase |
| Three Chamber | chambers | Throughput | Throughput | (%) |
| Single junction | 5 | 15.2 | 11.9 | 27.7 |
| PIN | 7 | 21.3 | 20.0 | 6.5 |
| Top Cell PIN | 5 | 14.7 | 12.7 | 15.7 |
| a-Si/mc-Si | 7 | 20.5 | 16.5 | 24.2 |
| tandem | | | | |
| Bottom Cell PIN | 5 | 7.3 | 5.4 | 35.2 |
| a-Si/mc-Si | 7 | 10.3 | 8.9 | 15.7 |
| tandem | | | | |

### II. GENERAL PROCESSING CONSIDERATIONS

The deposition methods of the present invention for the formation of solar cells may include the following deposition parameters. The substrate may have a surface area of 10,000 cm² or more, typically 40,000 cm² or more, and commonly 55,000 cm² or more. It is understood that after processing the substrate may be cut to form smaller solar modules.

The substrate temperature during deposition may be set to 400° C. or less, typically to between about 150° to about 400° C., and more commonly to between about 150° to about 250° C.

The spacing of the plasma electrodes during deposition may be set to between about 400 mil to about 1,200 mil, typically between about 400 mil and about 800 mil (1 mil=0.0254 mm). The electrodes are typically present in the form of the showerhead 110 and the substrate support 130 which are illustrated in FIG. 1. The plasma is generated between the electrodes.

In the EXAMPLES discussed below, the flow rates of plasma source gases are provided in sccm/L, where L is the interior chamber volume in Liters. The interior chamber volume is illustrated in FIG. 1 as process volume 106.

While silane (SiH₄) is commonly the plasma source gas used for the formation of various silicon-containing layers, other suitable gases may be used, including, but not limited to disilane (Si₂H₄), chlorosilane (SiH₂Cl₂), and combinations thereof. Hydrogen gas is used as a source of hydrogen, and may also serves as a carrier gas, but other carrier gases or hydrogen sources may be used. The dopants are typically provided with a carrier gas, such as hydrogen, argon, helium, or other suitable gases. In the process regimes disclosed herein, a total flow rate of hydrogen is provided. Therefore, if hydrogen gas is used as a carrier gas, such as for the dopant, the carrier gas flow rate should be subtracted from the total flow rate of hydrogen to determine how much additional hydrogen gas should be provided to the chamber.

The typical p-dopant is boron and a recommended boron source is a carbon-containing boron compound. In the embodiments described herein, the carbon-containing boron compound used is trimethylboron, TMB. Other carbon-containing boron source gases may be used as well, and the carbon-containing boron source may be selected from the group consisting of trimethylboron, triethylboron, tris(pentafluorophenyl)boron, decaborane, and combinations thereof, by way of example and not by way of limitation. The use of a carbon-containing dopant compound produces silicon carbide alloy within the silicon-containing structure, and this has been shown to be helpful in reducing the contamination of interfacially adjacent layers which are in contact with the p-doped silicon-containing layer.

The commonly used n-dopant is phosphorus, and the preferred phosphorus source is phosphine (PH₃). Other n-dopants may be used and other sources of phosphorus may be used.

The typical percent crystalline volume fraction of the microcrystalline silicon (mc-Si) p-doped layer of the first cell, the mc-Si n-doped layer of the first cell, and the mc-Si p-doped layer of the second cell is 20-80%, and commonly it is 50-70%. The typical percent crystalline volume fraction of the mc-Si intrinsic film of the second cell is 20-80%, and commonly it is 55-75%. It was surprising to find that if the microcrystalline intrinsic layer of the second cell had a crystalline volume fraction below 75%, a satisfactory conversion efficiency of the cell was achieved.

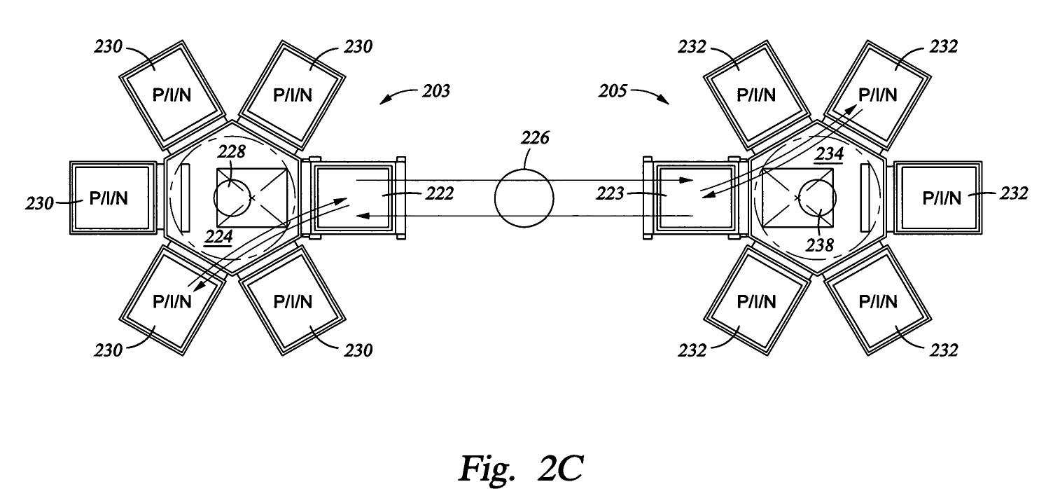

The base substrate upon which the thin film solar cells are deposited may comprise glass, polymer, metal, and combinations of these. For most current applications, the substrate has been glass. As illustrated in FIGS. 3, 4, and 5, a transparent conductive oxide (TCO) is deposited as a first layer over the glass. The TCO serves as the top electrode of the solar cell. Alternately, the electrode may be a transparent conductive polymer. The TCO may be (for example and not by way of limitation) zinc oxide, tin oxide, indium tin oxide, cadmium stannate, or a combination thereof. The TCO may be doped with a dopant, such as aluminum, boron, gallium, and others. The TCO is frequently formed of zinc oxide, doped to no more than 5 atomic % or less with dopants, and commonly comprises 2.5 atomic % or less of aluminum. In some instances, the substrate may be supplied for film deposition processing with the TCO layer already formed on top.

There has been industrywide consideration of the problem of boron contamination at the interface between a p-doped silicon-containing layer and an intrinsic silicon-containing layer. There are two sources of contamination. One source of contamination is boron which has been physisorbing onto the internal surfaces of the deposition chamber, such as the internal surfaces of chamber walls 107, surfaces of plenum 118, and surfaces of gas distribution shield 115, for example and not by way of limitation. The boron source gas reacts when molecules come in contact with these surfaces, and physisorb onto the surfaces. During the formation of the intrinsic layer, the generated plasma acts to etch this film and liberate the boron contained therein. As a result of this plasma recycling, the liberated boron then becomes incorporated into the intrinsic layer being formed. By keeping the interior surfaces of the chamber at a temperature lower than that of the substrate, the physisorption of boron and deposition of a film containing boron onto these interior surfaces is significantly reduced, thus improving the product which can be obtained from a “single” chamber process. In addition, it appears that convective heat transfer from the substrate support assembly 130 to the chamber walls 107 contributes to heating the walls and promoting physisorption of the boron source gas. Therefore, our method includes keeping the pressure within the reactor to below 100 torr.

A second source of contamination at the interface between a p-doped silicon-containing layer and a subsequently deposited intrinsic silicon layer is residual boron dopant which is present in the process chamber at the initiation of deposition of the intrinsic silicon-containing layer. Optionally, the processing chamber may be purged with a purge gas and/or a relatively high vacuum may be applied to the processing chamber to remove residual boron dopant compound from the process volume 106 (illustrated in FIG. 1). A typical purge gas is an inert gas such as argon or helium, by way of example and not by way of limitation. A purge time ranging from about 30 seconds to 180 seconds (applied after termination of deposition of the p-doped silicon-containing layer, and prior to initiation of deposition of the intrinsic silicon-containing layer) may be used, for example. The processing chamber may be pumped down subsequent to the inert gas purge, or may be pumped down without the use of an inert gas purge.

### III. EXAMPLES

### Example One

### Formation of a Single Junction Solar Cell

FIG. 3 shows a single stack (single junction) thin film solar cell, which includes a glass substrate 302, top electrode 304, p-layer 306, i-layer 308, n-layer 310, bottom electrode 312, and reflector 314. The interface between p-doped layer 306 and i-layer 308 is illustrated as 307.

The process steps described herein are those required for deposition of the thin film silicon-containing layers of the kind previously described, where the layers are deposited using PECVD. When all of the silicon-comprising layers in the solar cell are a-silicon-comprising layers (as they are for the single junction solar cell shown in FIG. 3), the PECVD depositions may be made using one of the single processing chambers 230 in cluster processing tool 203, of the kind shown in FIG. 2C. Each of the P/I/N processing chambers 230 for depositing silicon-comprising layers are essentially the same, and are capable of depositing a-silicon. It is also possible to carry out the PECVD depositions using one of the single processing chambers 232 in cluster processing tool 205, because these processing chambers are capable of depositing either mc-silicon-comprising layers or a-silicon-comprising layers. In addition, it is possible to carry out the PECVD depositions using one of the single processing chambers 250 or 252 shown in cluster processing tool 240, since the single processing chambers 250 are capable of depositing a-silicon-comprising layers, and the single processing chambers 252 are capable of depositing either mc-silicon-comprising layers or a-silicon-comprising layers.

For purposes of discussion, with reference to fabrication of the single junction solar cell of FIG. 3, the single processing chamber in which the solar cell is fabricated will be referred to as a processing chamber 230 of cluster processing tool 203. The substrate 302, with the top electrode 304 applied, was supplied to one of the P/I/N processing chambers 230. The substrate 302 was glass having a thickness of about 3.0 mm. However, other materials, such as a clear plastic, for example, may be used. The top electrode 304 is labeled as being a transparent conductive oxide, because such oxides are commonly used. The transparent conductive oxide (TCO) layer 304 was SnO₂, which had been deposited using an LPCVD technique known in the art. The SnO₂ layer thickness was set within a range from about 600 nm to 12,000 nm. The TCO layer 304 can be, for example and not by way of limitation, SnO₂, ZnO, or other oxide layers of the kind previously described herein. Other materials, such as a transparent conductive polymeric film, for example, may also be used.

The substrate 302 with TCO layer 304 applied was placed in a process chamber 230 with the TCO surface exposed for deposition of p-doped layer 306 of an a-silicon comprising material. The p-doped layer 306 was deposited in a PECVD chamber 230 which has parallel electrodes of the kind previously described herein, where the spacing between electrodes was about 550 mil (thousandths of an inch). The pressure in the process chamber was approximately 2.5 Torr, and the deposition temperature was about 200° C. The RF power density was about 0.06 W/cm³, and the power frequency was 13.56 MHz. The plasma source gases for the p-doped film deposition were SiH₄ at 3.3 sccm/L, H₂ at 16.8 sccm/L, CH₄ at 3.2 sccm/L, and TMB at 0.01 sccm/L. The ratio of H₂:SiH₄ was 5.8:1. The film deposition time is about 14 seconds, the deposited film thickness is 113 Å, and the film deposition rate is 500 Å/min.

Subsequent to deposition of the p-doped layer, An argon purge at 8 Torr was performed for a time period of about 60 seconds, followed (this step is optional) by a pump-down with a turbo pump, down to 2×10⁻⁶ Torr, to remove residual gaseous boron species.

The i-layer 308 was subsequently deposited over the surface of the p-doped layer 306 in the same PECVD chamber 230. The spacing of the parallel electrodes was about 550 mil. The pressure in the process chamber was approximately 3 Torr, and the deposition temperature was about 200° C. The RF power density was about 0.05 W/cm³ and the power frequency was 13.56 MHz. The plasma source gases for the i-layer 308 of a-silicon were SiH₄ at 3.3 sccm/L and H₂ at 41.7 sccm/L. The ratio of H₂:SiH₄ was 12.5. The film deposition time was about 500 seconds, the deposited film thickness was 2,700 Å, and the film deposition rate was 310 Å/min.

The n-doped layer 310 was subsequently deposited over the surface of the i-layer 308 in the same PECVD chamber 230. The spacing of the parallel electrodes was about 550 mil. The pressure in the process chamber was approximately 1.5 Torr, and the deposition temperature was about 200° C. The n-doped layer was deposited as a dual layer, where the first portion of the layer was deposited at an RF power density was about 0.09 W/cm³ and the power frequency was 13.56 MHz. The plasma source gases for the first portion of n-layer 310 which comprised a-silicon were SiH₄ at 4.4 sccm/L, H₂ at 21.6 sccm/L, and PH₃ at 0.003 sccm/L. The ratio of H₂:SiH₄ was 5:1. The film deposition time was about 24 seconds, the deposited film thickness was 200 Å, and the film deposition rate was 500 Å/min. The second portion of the layer was deposited at an RF power density which was about 0.07 W/cm³ and the power frequency was 13.56 MHz. The plasma source gases for the second portion of n-layer 310 which comprised a-silicon were SiH₄ at 1.0 sccm/L, H₂ at 3.0 sccm/L, and PH₃ at 0.02 sccm/L. The ratio of H₂:SiH₄ was 8:1. The film deposition time was about 10 seconds, the deposited film thickness was 80 Å, and the film deposition rate was 300 Å/min.

Subsequent to the PECVD deposition of the p-doped layer, i-layer, and n-doped layer, the substrate was removed from processing chamber 230 of the “single” chamber cluster processing system 203 shown in FIG. 2C and was sent to a sputtering chamber where the bottom TCO layer of ZnO and a reflective layer of aluminum was applied using sputtering techniques of the kind known in the art.

The collection efficiency for the single junction solar cell described was in the range of about 9.5%.

### Example Two

### Formation of a Dual/Tandem Junction Solar Cell

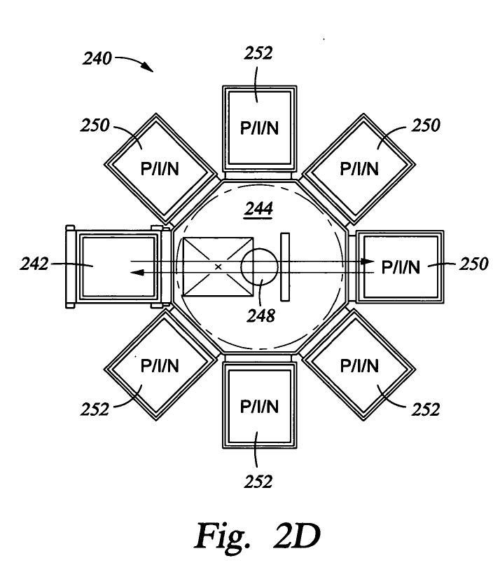

FIG. 4 shows a dual stack (dual junction) thin film solar cell, which includes a glass substrate 402; top electrode 404; a top p-i-n cell including: a p-doped layer comprising a-silicon 406; i-layer comprising a-silicon 408; and a dual n-doped layer, including a first n-doped layer comprising a-silicon 410, and a second n-doped layer comprising mc-silicon 412; a bottom p-i-n cell including: a p-doped layer comprising mc-silicon 414; i-layer comprising mc-silicon 416; n-doped layer comprising a-silicon 418; a bottom electrode of ZnO TCO 420, and an aluminum or silver reflector 422. An example interface between p-doped layer 406 and i-layer 408 is designated as 407.

The process steps described herein are limited to the steps required for deposition of the thin film silicon-containing layers previously described, where the layers are deposited using PECVD. The PECVD depositions are made using a cluster processing system 240 of the kind shown in FIG. 2D, where a portion of the P/I/N chambers 250 for depositing silicon-containing layers were configured to deposit an a-silicon-comprising layer, and a portion of the P/I/N chambers 252 for depositing silicon-containing layers were configured to deposit mc-silicon (or a-silicon)-comprising layers. However, it would be possible to deposit all of the p, i, and n layers in a single chamber, a 252 chamber, which is capable of depositing either a mc-silicon-comprising layer or an a-silicon-comprising layer. The reason for using a particular processing chamber then depends on the length of time required to deposit a given layer, and the most beneficial use of the chambers in the cluster processing tool. In any case, in the event that one processing chamber goes down, since all of the solar cell layers can be deposited in any single processing chamber capable of depositing both mc-silicon-comprising layers and a-silicon-comprising layers, and since there are a plurality of chambers capable of this, the entire system is not shut down, it is merely slowed down.

With reference to FIG. 4, the following method describes the formation of a tandem solar cell with an SnO upper TCO. The substrate 402 was glass having a thickness of about 3.0 mm. However, other materials, such as a clear plastic, for example, may be used. The top electrode, a transparent conductive oxide (TCO) layer 404 was SnO₂ which was deposited using a sputtering technique known in the art. The SnO₂ layer was about 600 nm to about 12,000 nm. The TCO layer 404 can be, for example and not by way of limitation, ZnO or other oxide layers of the kind previously described herein. Other materials, such as a transparent conductive polymeric film, for example, may also be used.

The substrate 402 with TCO layer 404 applied was placed in a process chamber 250 of a processing cluster chamber 240 with the TCO surface exposed for deposition of p-doped layer 406 of an a-silicon comprising material. The p-doped layer 406 of the top cell was deposited in a PECVD chamber 250 having parallel electrodes of the kind previously described herein, where the spacing between electrodes was about 550 mil (thousandths of an inch). The pressure in the process chamber was approximately 3 Torr, and the deposition temperature was about 200° C. The RF power density was about 0.1 W/cm³ and the power frequency was 13.56 MHz. The plasma source gases for the p-doped film deposition were SiH₄ at 3.3 sccm/L, H₂ at 16.8 sccm/L, and TMB at 0.01 sccm/L. The ratio of H₂:SiH₄ was 5.8:1. The film deposition time was about 12 seconds, the deposited film thickness was 100 Å, and the film deposition rate was 500 Å/min.

Subsequent to deposition of the p-doped layer, a hydrogen purge at 2 Torr was performed for a time period of about 60 seconds, followed by a pump-down with a turbo pump down to 2×10⁻⁶ Torr (an optional step), to remove residual gaseous boron species.

An a-silicon comprising i-layer 408 was subsequently deposited over the surface of the p-doped layer 406 in the same PECVD chamber 250. The spacing of the parallel electrodes was about 550 mil (thousandths of an inch). The pressure in the process chamber was approximately 3 Torr, and the deposition temperature was about 200° C. The RF power density was about 0.05 W/cm³ and the power frequency was 13.56 MHz. The plasma source gases for the i-layer 308 of a-silicon were SiH₄ at 3.3 sccm/L and H₂ at 27.8 sccm/L. The ratio of H₂:SiH₄ was 8.3:1. The film deposition time was about 375 seconds, the deposited film thickness was 2,500 Å, and the film deposition rate was 400 Å/min.

The n-doped layer was a dual layer of silicon-containing material, where the first portion 410, which comprised a-silicon was deposited over the surface of the i-layer 410 in the same PECVD chamber 250 as the chamber in which the i-layer was deposited. The second portion 412 of the n-doped layer was deposited in a PECVD chamber 252 which was configured to deposit mc-silicon. The spacing of the parallel electrodes was about 550 mil in each process chamber. The pressure in each process chamber was approximately 2 Torr, and the deposition temperature in each chamber was about 200° C. The first portion 410 of the n-doped layer was deposited at an RF power density was about 0.1 W/cm³ and the power frequency was 13.56 MHz. The plasma source gases for the first portion 410 of the n-doped layer which comprised a-silicon were SiH₄ at 4.4 sccm/L, H₂ at 21.6 sccm/L, and PH₃ at 0.003 sccm/L. The ratio of H₂:SiH₄ was 5:1. The film deposition time was about 6 seconds, the deposited film thickness was 50 Å, and the film deposition rate was 500 Å/min. The second portion 412 of the n-doped layer was deposited at an RF power density of about 0.4 W/cm³ and the power frequency was 13.56 MHz. The plasma source gases for the second portion 412 of n-layer, which comprised mc-silicon, were SiH₄ at 0.4 sccm/L, H₂ at 120.0 sccm/L, and PH₃ at 0 004 sccm/L. The ratio of H₂:SiH₄ was 300:1. The film deposition time was about 80 seconds, the deposited film thickness was 200 Å, and the film deposition rate was 150 Å/min.

Subsequent to deposition of the top cell, the second, bottom, cell of the tandem was deposited. The p-doped layer 414 of the bottom cell was deposited in a PECVD chamber 252 having parallel electrodes of the kind previously described herein, where the spacing between electrodes was about 550 mil (thousandths of an inch). The pressure in the process chamber was approximately 9 Torr, and the deposition temperature was about 200° C. The RF power density was about 0.15 W/cm³ and the power frequency was 13.56. The plasma source gases for the p-doped mc-silicon-comprising film deposition were SiH₄ at 0.2 sccm/L, H₂ at 125 sccm/L, and TMB at 0.0005 sccm/L. The ratio of H₂:SiH₄ was 650:1. The film deposition time was about 200 seconds, the deposited film thickness was 200 Å, and the film deposition rate was 60 Å/min.

Subsequent to deposition of the p-doped layer, a hydrogen purge at 2 Torr was performed for a time period of about 60 seconds, followed by a pump-down with a turbo pump down to 2×10⁻⁶ Torr, to remove residual gaseous boron species.

An mc-silicon comprising i-layer 416 of the second cell was subsequently deposited over the surface of the p-doped layer 414 in the same PECVD chamber 252. The spacing of the parallel electrodes was about 550 mil. The pressure in the process chamber was approximately 9 Torr, and the deposition temperature was about 200° C. The RF power density was about 1.01 W/cm³ and the power frequency was 13.56 MHz. The i-layer comprising mc-silicon was deposited in four steps, due to the overall thickness required for the i-layer. The plasma source gases for the first deposition of i-layer 416 of mc-silicon were SiH₄ at 2.3 sccm/L and H₂ at 227.6 sccm/L. The ratio of H₂:SiH₄ was approximately 100:1. The film deposition time was about 415 seconds, the deposited film thickness was 4,500 Å, and the film deposition rate was 650 Å/min. The plasma source gases for the second deposition of i-layer 416 of mc-silicon were SiH₄ at 2.3 sccm/L and H₂ at 216.3 sccm/L. The ratio of H₂:SiH₄ was approximately 95:1. The film deposition time was about 415 seconds, the deposited film thickness was 4,500 Å, and the film deposition rate was 650 Å/min. The plasma source gases for the third deposition of i-layer 416 of mc-silicon were SiH₄ at 2.3 sccm/L and H₂ at 204.9 sccm/L. The ratio of H₂:SiH₄ was approximately 90:1. The film deposition time was about 415 seconds, the deposited film thickness was 4,500 Å, and the film deposition rate was 650 Å/min. The plasma source gases for the fourth deposition of i-layer 416 of mc-silicon were SiH₄ at 2.3 sccm/L and H₂ at 193.5 sccm/L. The ratio of H₂:SiH₄ was approximately 85:1. The film deposition time was about 415 seconds, the deposited film thickness was 4,500 Å, and the film deposition rate was 650 Å/min.

The n-doped layer 418 was subsequently deposited over the surface of the i-layer 416 in a PECVD process chamber 250 of cluster processing system 240. This process chamber was used because the n-doped layer of the second cell comprised a-silicon. The spacing of the parallel electrodes was about 550 mil. The pressure in the process chamber was approximately 1.5 Torr, and the deposition temperature was about 200° C. The n-doped layer was deposited as a dual layer, where the first portion of the layer was deposited at an RF power density of 0.1 W/cm³. The plasma source gases for the first portion of n-layer 418 which comprised a-silicon were SiH₄ at 4.4 sccm/L, H₂ at 21.6 sccm/L, and PH₃ at 0.003 sccm/L. The ratio of H₂:SiH₄ was 5:1. The film deposition time was about 24 seconds, the deposited film thickness was 200 Å, and the film deposition rate was 500 Å/min. The second portion of the n-doped layer was deposited at an RF power density was about 0.07 W/cm³ and the power frequency was 13.56 MHz. The plasma source gases for the second portion of n-layer 418 which comprised a-silicon were SiH₄ at 1.0 sccm/L, H₂ at 3.0 sccm/L, and PH₃ at 0.03 sccm/L. The ratio of H₂:SiH₄ was 8.3:1. The film deposition time was about 16 seconds, the deposited film thickness was 80 Å, and the film deposition rate was 300 Å/min.

Subsequent to the PECVD deposition of the bottom cell of the tandem, the substrate was removed from processing chamber 250 of the “single” chamber cluster processing system 240 shown in FIG. 2D and was sent to a sputtering chamber where the bottom TCO layer of ZnO and a reflective layer of aluminum or silver was applied using sputtering techniques of the kind known in the art.

The collection efficiency of the tandem, two cell, solar cell described with reference to FIG. 4 was about 11%. We are confident that this 11% collection efficiency can be obtained in a single processing chamber.

For example, the p-layer, the i-layer, and first portion of the n-layer of the top solar cell were deposited in a single 250 processing chamber. However, for purposes of processing efficiency, since the mc-silicon-comprising i-layer of the bottom solar cell requires a considerably longer deposition time (415×4=1660 seconds) to deposit than other mc-silicon-comprising and a-silicon comprising layers in the solar cell, it is more economical to deposit at least this i-layer in a second, 252 processing chamber. As previously mentioned, the 252 processing chambers are capable of depositing both mc-silicon-comprising layers and a-silicon-comprising layers, and there are a plurality of these 252 processing chambers in cluster tool 240. This provides excellent flexibility when one of the layer deposition steps requires a substantially longer period of time. While there are some 250 processing chambers which are configured to deposit a-silicon-comprising layers only, because these chambers are less expensive to fabricate, it would be possible to have all of the processing chambers in cluster tool 240 be the 252 processing chambers.

### Example Three

### Formation of an Alternative Dual/Tandem Junction Solar Cell

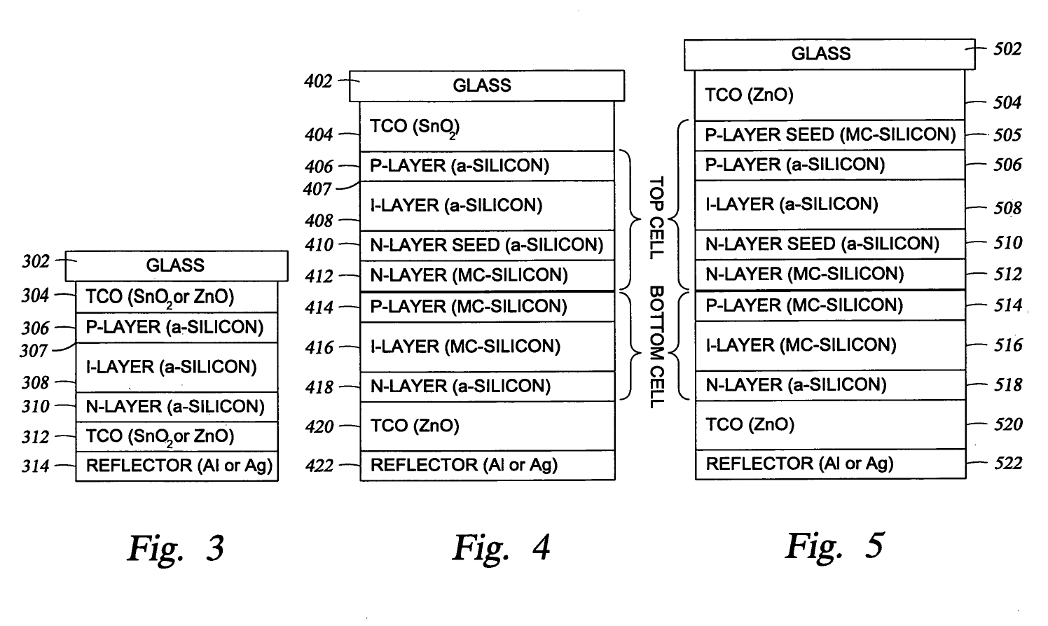

FIG. 5 shows an alternative dual stack (dual junction) thin film solar cell, which includes a glass substrate 502; top electrode 504; a top p-i-n cell including: a dual p-doped layer comprising an upper portion of mc-silicon 505 and a lower portion of a-silicon 506; i-layer comprising a-silicon 508; and a dual n-doped layer, including a first n-doped layer comprising a-silicon 510, and a second n-doped layer comprising mc-silicon 512; a bottom p-i-n cell including: a p-doped layer comprising mc-silicon 514; i-layer comprising mc-silicon 516; n-doped layer comprising a-silicon 518; a bottom electrode of ZnO TCO 520, and an aluminum or silver reflector 522.

The process steps described herein are limited to the steps required for deposition of the thin film silicon-containing layers previously described, where the layers are deposited using PECVD. The PECVD depositions are made using a cluster processing system 240 of the kind shown in FIG. 2D, where a portion of the P/I/N chambers 250 for depositing silicon-containing layers were configured to deposit a-silicon, and a portion of the P/I/N chambers 252 for depositing silicon-containing layers were configured to deposit mc-silicon.

With reference to FIG. 5, the following method describes the formation of a tandem solar cell with a ZnO upper TCO. The substrate 502 was glass having a thickness of about 3.0 mm. However, other materials, such as a clear plastic, for example, may be used. The top electrode, a transparent conductive oxide (TCO) layer 504 was ZnO which was deposited using a sputtering technique known in the art. The TCO layer 504 can be, for example and not by way of limitation, SnO₂ or other oxide layers of the kind previously described herein. Other materials, such as a transparent conductive polymeric film, for example, may also be used.

The substrate 502 with TCO layer 504 applied was placed in a process chamber 252 of a processing cluster chamber 240 with the TCO surface exposed for deposition of p-doped layer. The p-doped layer of the top cell was a dual layer, where the upper portion of the p-doped layer was a mc-silicon comprising layer deposited in a PECVD chamber 252 and the lower portion of the p-doped layer was an a-silicon comprising layer deposited in a PECVD chamber 250. Each PECVD processing chamber included parallel electrodes of the kind previously described herein, where the spacing between electrodes was about 550 mil (thousandths of an inch). During deposition of the upper portion 505 of the p-doped layer which comprised mc-silicon, in process chamber 252, the pressure in the process chamber was approximately 9 Torr, and the deposition temperature was about 200° C. The RF power density was about 0.2 W/cm³, and the power frequency was 13.56 MHz. The plasma source gases for deposition of the upper portion 505 of the p-doped mc-silicon film deposition were SiH₄ at 0.2 sccm/L, H₂ at 125 sccm/L, and TMB at 0.0005 sccm/L. The ratio of H₂:SiH₄ was 650:1. The deposition time was 40 seconds, the layer thickness was 100 Å, and the deposition rate was 150 Å/min. During deposition of the lower portion 506 of the p-doped layer which comprised a-silicon, in process chamber 250, the pressure in the process chamber was about 3 Torr, and the deposition temperature was about 200° C. The plasma source gases for the lower portion 506 of the p-doped a-silicon film deposition were SiH₄ at 3.3 sccm/L, H₂ at 16.8 sccm/L, and TMB at 0.01 sccm/L. The ratio of H₂:SiH₄ was 5.8:1. The RF power density was about 0.1 W/cm³ and the power frequency was 13.56 MHz. The deposition time was 12 seconds, the layer thickness was 100 Å, and the deposition rate was 500 Å/min.

Subsequent to deposition of the p-doped layer, a hydrogen purge at 2 Torr was performed for a time period of about 60 seconds, followed by a pump-down with a turbo pump down to 2×10⁻⁶ Torr (an optional step), to remove residual gaseous boron species.

An a-silicon comprising i-layer 508 was subsequently deposited over the surface of the p-doped layer 506 in the same PECVD chamber 250. The spacing of the parallel electrodes was about 550 mil. The pressure in the process chamber was approximately 2 Torr, and the deposition temperature was about 200° C. The RF power density was about 0.1 W/cm³ and the power frequency was 13.56 MHz. The plasma source gases for the i-layer 508 of a-silicon were SiH₄ at 3.3 sccm/L and H₂ at 27.8 sccm/L. The ratio of H₂:SiH₄ was 8.3:1. The film deposition time was about 375 seconds, the deposited film thickness was 2,500 Å, and the film deposition rate was 400 Å/min.

The remaining layers of this alternative tandem, two cell solar cell, including: the bottom n-doped layer of the top solar cell, where the n-doped layer was a dual layer including a first a-silicon-comprising portion 510 and a second mc-silicon-comprising portion 512; the top p-doped mc-crystalline silicon-comprising layer 514 of the bottom solar cell; the mc-silicon-comprising i-layer 516 of the bottom solar cell; the n-doped a-silicon-comprising n-layer 518 of the bottom solar cell; the ZnO TCO layer 520; and the reflector layer 522 were all produced in the manner described in Example Two.

The collection efficiency of the alternative tandem, two cell, solar cell described with reference to FIG. 5 was about 12%. Again, this alternative tandem two cell solar cell can be produced in a single P/I/N chamber, for the same reasons as provided with respect to the tandem two cell solar cell described in Example Two.

While the invention has been described in detail above with reference to several embodiments, various modifications within the scope and spirit of the invention will be apparent to those of working skill in this technological field. Accordingly, the scope of the invention should be measured by the appended claims.

1. A method of forming a p-i-n solar cell comprising:
a) providing a single PECVD processing chamber configured to deposit a p-doped layer, an i-layer, and an n-doped layer;
b) placing a substrate having a surface area of 1 square meter or greater within said PECVD processing chamber;
c) forming a p-doped layer upon said substrate;
d) forming an i-layer overlying said p-doped layer; and
e) forming an n-doped layer overlying said i-layer,
wherein said p-doped layer, said i-layer, and said n-doped layer are all formed in the same processing chamber.

2. A method in accordance with claim 1, wherein a stacked solar cell structure is formed by carrying out the following additional steps, comprising:
f) forming a second p-doped layer overlying said n-doped layer of step e);
g) forming a second i-layer overlying said second p-doped layer of step f); and
h) forming a second n-doped layer overlying a surface of said second i-layer of step g).

3. A method in accordance with claim 2, wherein the processing steps for the top cell of the stacked solar cell are carried out in a PECVD processing chamber configured to deposit an a-silicon-comprising p-doped layer an a-silicon-comprising i-layer, and a dual n-doped layer, wherein a top portion of the dual n-doped layer comprises a-silicon, and a bottom portion of the dual n-doped layer comprises mc-silicon.

4. A method in accordance with claim 3, wherein the processing steps for the bottom cell of the stacked solar cell are carried out in a PECVD processing chamber configured to deposit a mc-silicon-comprising p-doped layer, a mc-silicon-comprising i-layer, and an a-silicon-comprising n-doped layer.

5. A method in accordance with claim 3, wherein said PECVD processing chamber is configured to deposit either an a-comprising silicon layer or a mc-comprising silicon layer.

6. A method in accordance with claim 4, wherein said PECVD processing chamber is configured to deposit either an a-comprising silicon layer or a mc-comprising silicon layer.

7. A method in accordance with claim 1, wherein said substrate comprises an optically transparent electrode layer upon which said p-layer is deposited.

8. A method in accordance with claim 7, wherein said optically transparent electrode layer is a conductive oxide selected form the group consisting of tin oxide, zinc oxide, indium tin oxide, cadmium stannate, or combinations thereof

9. A method in accordance with claim 7, wherein said optically transparent electrode layer is a conductive polymer.

10. A method in accordance with claim 1, or claim 2, or claim 3, or claim 4, wherein said p-doped layer is doped with a dopant selected from the group consisting boron, aluminum, gallium, and combinations thereof.

11. A method in accordance with claim 10, wherein said dopant is a carbon-containing dopant.

12. A method in accordance with claim 11, wherein said dopant is a boron-containing dopant.

13. A method in accordance with claim 12, wherein said dopant is selected from the group consisting of trimethylboron, triethylboron, boron trifluoride, tris(pentafluorophenyl) boron, pentaborane, decaborane, and combinations thereof.

14. A method of forming a p-i-n solar cell, comprising:
a) providing a single PECVD processing chamber configured to deposit a p-doped layer, a i-layer, and an n-doped layer;
b) placing a substrate having a surface area greater than 1 square meter or greater within said PECVD processing chamber;
c) heating said substrate to a minimum temperature of 150° C. or greater;
d) forming a p-doped layer which includes a silicon-comprising layer doped with a carbon-comprising boron compound upon said substrate, wherein process chamber wall surfaces adjacent said substrate are held at a temperature of at least 50° C. lower than said substrate temperature;
e) forming an i-layer overlying said p-doped layer; and
f) forming an n-doped layer overlying said i-layer.

15. A method in accordance with claim 14, wherein said carbon-containing boron compound is selected from the group consisting of trimethylboron, triethylboron, boron trifluoride, tris(pentafluorophenyl)boron, pentaborane, decaborane, and combinations thereof.

16. A cluster processing system comprising at least one single processing chamber which is configured to deposit a p-doped layer, an i-layer, and an n-doped layer.

17. A cluster processing system in accordance with claim 16, wherein said at least one single processing chamber is configured to deposit either an a-silicon-comprising layer or a mc-silicon-comprising layer.
